(19) United States
(12) Patent Application Publication
(10) Pub. No.: US 2006/0145192 A1
(43) Pub. Date: Jul. 6, 2006

(54) Denise array structure for non-volatile semiconductor memories

(76) Inventors: Michiel Jos Van Duuren, Leuven (BE); Robertus Theodorus Fransiscus Van Schaijk, Leuven (BE)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(21) Appl. No.: 10/515,643

(22) PCT Filed: May 19, 2003
(86) PCT No.: PCT/IB03/02143

§ 371 Date: Nov. 24, 2004

(30) Foreign Application Priority Data
May 31, 2002 (EP) 02077155.6

(51) Int. Cl. H01L 27/10

(52) U.S. Cl. 257/202; 257/E27.108

(57) ABSTRACT

The present invention describes an array structure (10) for non-volatile semiconductor memory elements (14, 16) with a high area density. This high density is obtained by the combination of a commonly used virtual ground scheme and a 2-dimensional array of memory elements (14, 16). Wordlines (18, 20) connecting memory elements (14, 16) in a row or a column cross each other at insulated cross-points (22). Furthermore, the invention describes a possible fabrication process for such memory arrays.

The present invention relates to the field of non-volatile semiconductor memories such as floating gate memories for example and methods of operating the same. More particularly, the present invention relates to a dense array structure of such memory elements, non-volatile memories comprising such dense array structure, and methods for manufacturing such dense array structures.

Non-volatile memories (NVMs) are used in a wide variety of commercial and military electronic devices and equipment, such as e.g. hand-held telephones, radios and digital cameras. The market for these electronic devices continues to demand devices with a lower voltage, lower power consumption and a decreased chip size.

Flash memory has a grid of columns and rows with at each intersection a MOSFET with a (or a plurality of) floating gate(s) (FG) between a control gate (CG) and a channel region, the floating gate(s) and the control gate being separated by a thin dielectric layer, generally referred to as “inter poly dielectric (IPD)” when polysilicon is used for the FG and CG. With the improvement of fabrication technologies, the floating gate size has been reduced to sub-micron scale. These devices are basically special types of floating gate transistors in which electrons (or holes) are injected in a floating gate, and tunnel through an oxide barrier. Charges stored in the floating gate modify the device threshold voltage. In this way, data is stored. The CG controls the FG. Flash memory cells can be erased in blocks instead of one byte at a time.

An EEPROM cell and architecture formed on a silicon substrate is known from U.S. Pat. No. 4,763,299. The architecture described provides an EEPROM array with a higher density than other prior art architectures. A set of bitlines is aligned parallel a vertical bitline axis. The channels of the EEPROM cells are aligned along channel axes oriented ±45° from the bitline axis. Wordlines of the array form a zigzag pattern, the wordlines having horizontal segments and segments aligned along the channel axes.

U.S. Pat. No. 5,787,035 and U.S. Pat. No. 5,982,671 relate to a memory cell array in which four memory cells hold a drain region or a source region in common. The memory cells are floating gate (FG)/control gate (CG) stacks. The control gates of a row of CG are electrically interconnected, the interconnections forming wordlines. The wordlines are physically formed in a zigzag pattern. The size of the array is decreased by decreasing the area occupied by the contact holes, as four memory cells hold a single source region or a single drain region in common.

It is a disadvantage of the prior art cell architectures as described above that they use wordlines in a zigzag pattern, which inevitably leads to large cells. This is due to the lithographic process used in manufacturing such devices: imaging straight lines is easier than imaging a zigzag pattern. Moreover, the zigzag pattern can cause yield losses in large arrays, because of the risk of shorts or opens. Finally, the transistor matching is sub-optimal when the polysilicon gate bends close to the transistor edges, especially in the case of misalignment between the active channel area and gate masks.

It is an object of the present invention to provide a memory cell and an accompanying array architecture with an area density which is higher than what is known from prior art memory cells, as well as to provide a method for manufacturing such memory cells.

The above objectives are accomplished by the devices and methods according to the present invention.

The present invention provides an array of semiconductor memory devices logically organized in rows and columns. According to the invention, semiconductor memory devices on a row are connected by a first wordline and semiconductor memory devices on a column are connected by a second wordline, whereby the first and second wordlines cross each other. The crossing of the first and second wordlines is an insulated crossing. Due to the crossing wordlines, area density of memory cells can be higher than what is known from prior art memory cells. Cell sizes are smaller than prior art cell sizes if the same design rules are used.

The semiconductor memory devices may be connected in a virtual ground scheme, which allows to make very small cells.

The semiconductor memory devices may be transistors having identical or different transistor length.

The semiconductor memory devices in the array may be stacked gate floating gate memories, where charges are stored in a floating gate, or charge trapping devices, where charges are stored in a charge trapping medium or layer. Charge trapping devices can be of a type to store one bit, or of a type to store two bits.

The present invention also provides a non-volatile memory including an array of semiconductor memory devices as described above.

The present invention furthermore provides a method for manufacturing in or on a semiconductor substrate having a surface, an array of semiconductor memory devices logically organized in rows and columns. The method comprises the steps of providing a first wordline and providing a second wordline, the first and second wordlines crossing each other. The step of providing the first wordline and the step of providing the second wordline may comprise depositing a conductive layer.

The method may furthermore comprise a step of providing insulation between the first wordline and the second wordline. This step may comprise providing an insulator in a direction away from the substrate surface. It may also comprise providing a lateral insulator.

The method may furthermore comprise a step of manufacturing the semiconductor memory devices. The step of manufacturing the semiconductor memory devices may comprises providing transistors with identical or with different transistor length.

The step of manufacturing the semiconductor memory devices may comprise steps for manufacturing stacked gate floating gate transistors. Alternatively it may comprise steps for manufacturing charge trapping devices.

These and other features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

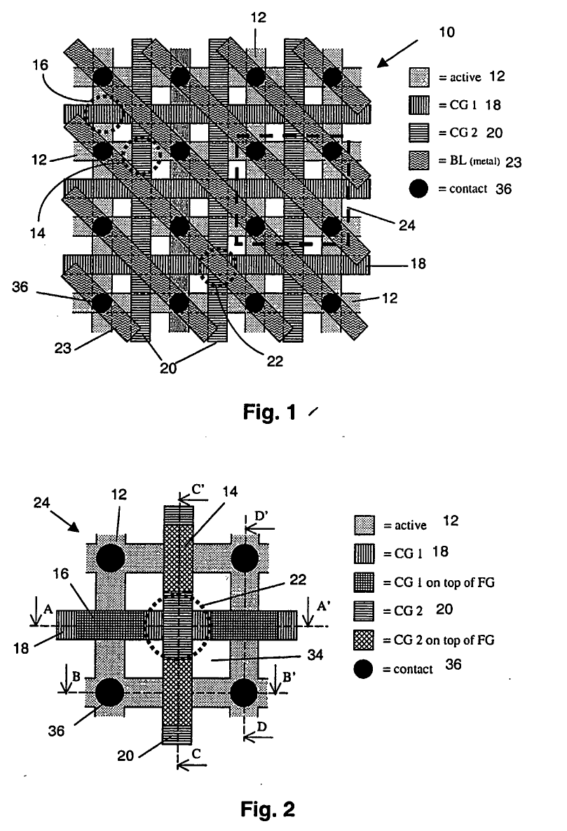

FIG. 1 is a top view of a part of a memory array according to a first embodiment of the present invention, showing active regions, insulating regions, overlapping wordlines in row-direction and column-direction and diagonal bitlines.

FIG. 2 is an enlarged view showing more detail of a first embodiment of one unit cell of the array of FIG. 1, but with the bitlines deleted for clarity purposes, the memory cells in this embodiment being stacked FG transistor elements.

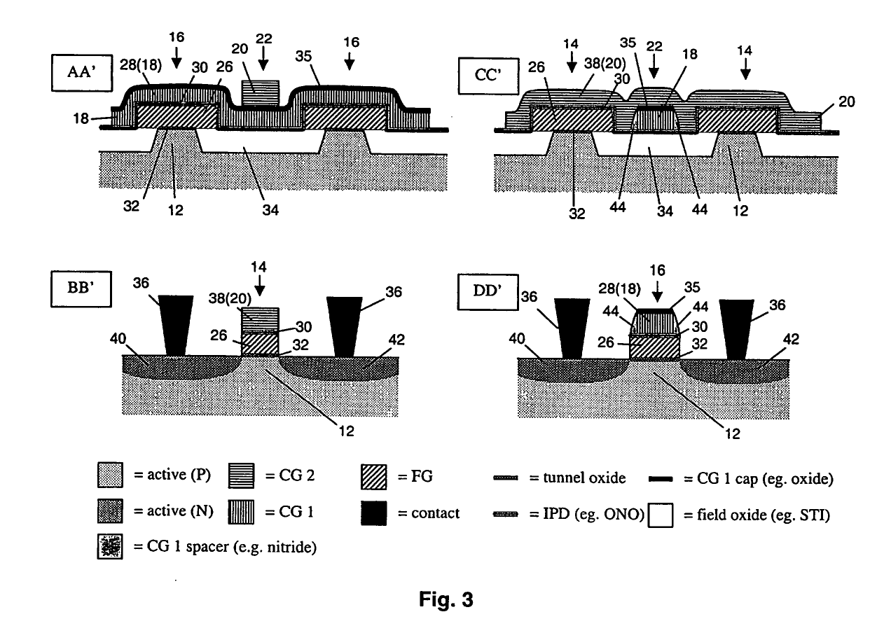

FIG. 3 shows four cross-sections of a first embodiment of the unit cell of FIG. 2, according to the lines AA′, BB′, CC′ and DD′ in FIG. 2.

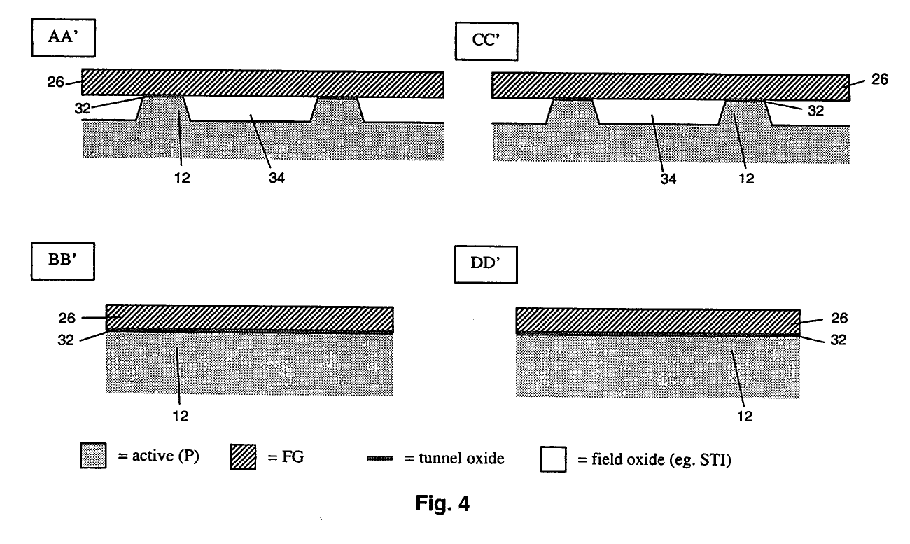

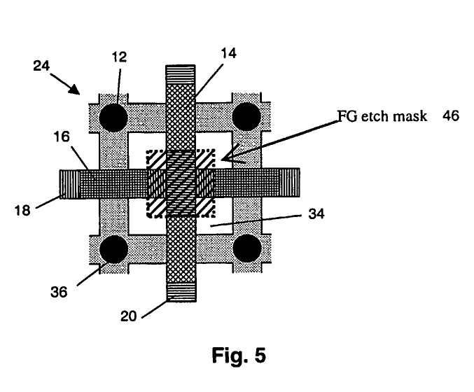

FIG. 4 shows four cross-sections of an uncompleted unit cell, after field oxide definition, growth of a tunnel oxide layer and blanket FG polysilicon layer deposition.

FIG. 5 shows a unit cell as in FIG. 2, and illustrates the mask to be used for etching squares in the FG polysilicon layer.

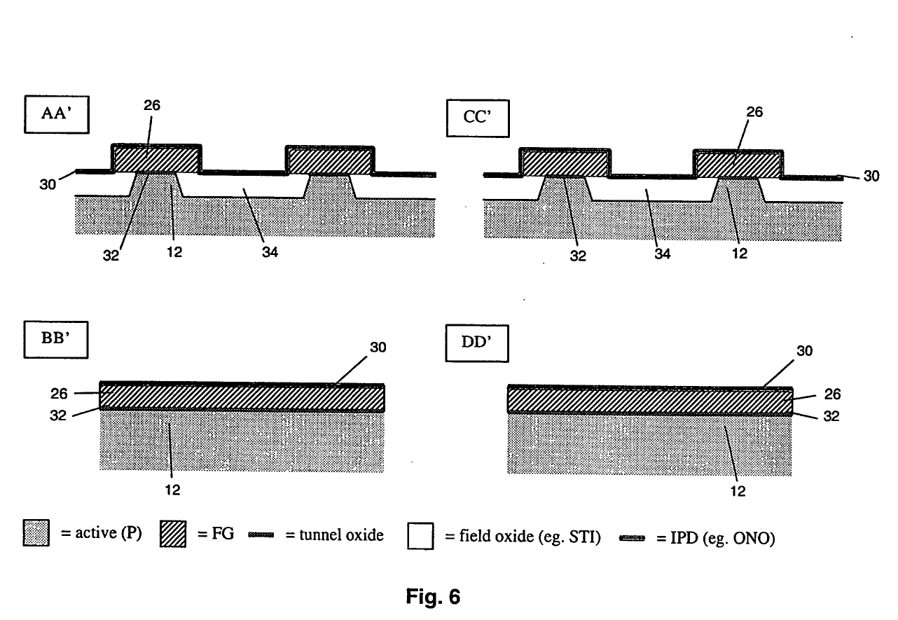

FIG. 6 shows four cross-sections of an uncompleted unit cell, after squares have been etched in the FG polysilicon using the mask of FIG. 5, and after an IPD layer has been formed over what is left from the FG polysilicon layer.

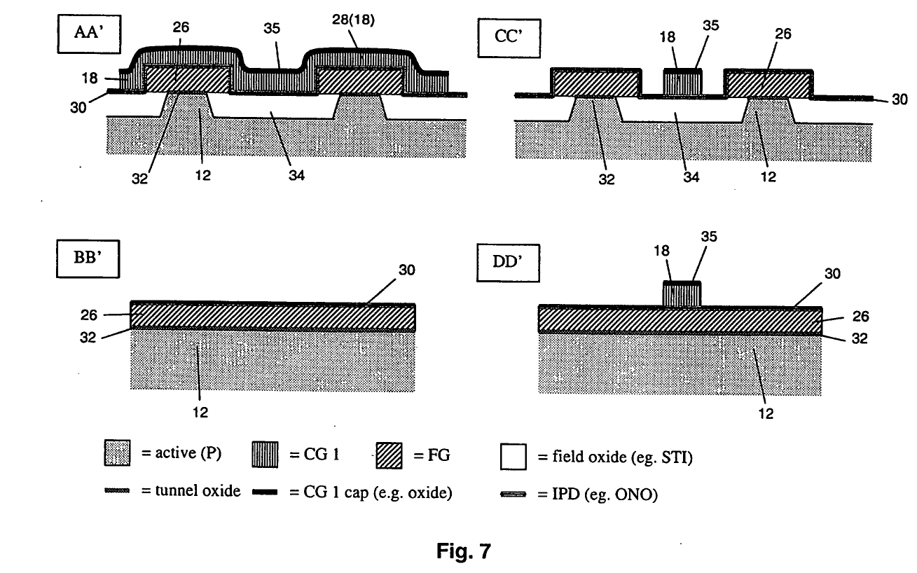

FIG. 7 shows four cross-sections of an uncompleted unit cell, after deposition and patterning of a first control gate polysilicon layer with a capping layer on top, thus forming first wordlines.

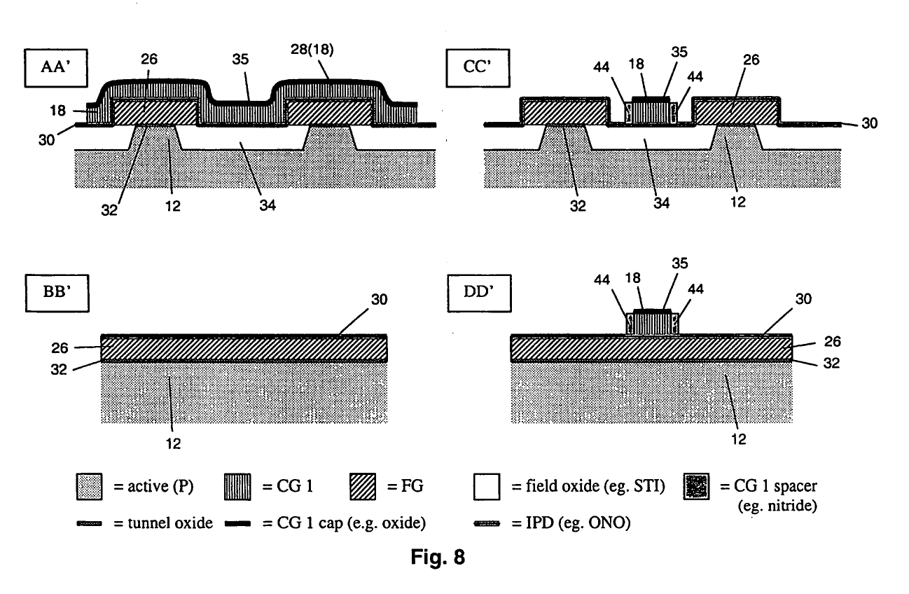

FIG. 8 shows four cross-sections of an uncompleted unit cell, after formation of insulating spacers or layers alongside the first wordlines.

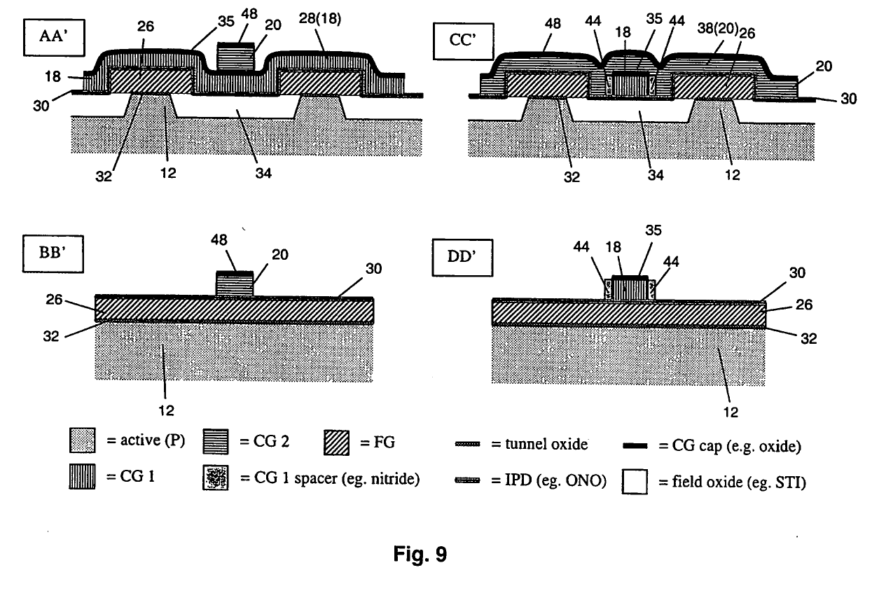

FIG. 9 shows four cross-sections of an uncompleted unit cell, after deposition and patterning of a second CG polysilicon layer with a capping layer on top, thus forming second wordlines which cross the first wordlines without being in mutual electrical contact.

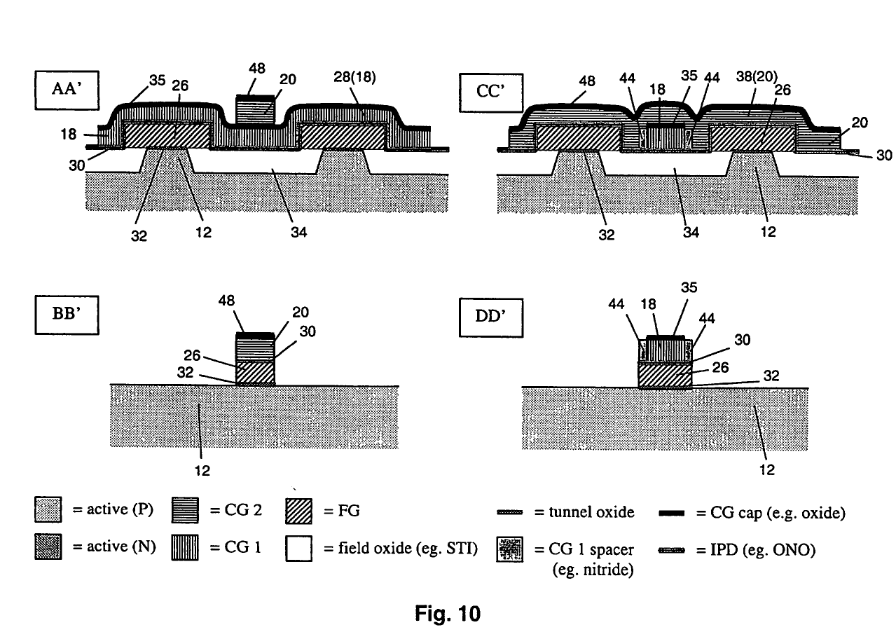

FIG. 10 shows four cross-sections of an uncompleted unit cell, after having etched the IPD layer and the FG polysilicon layer.

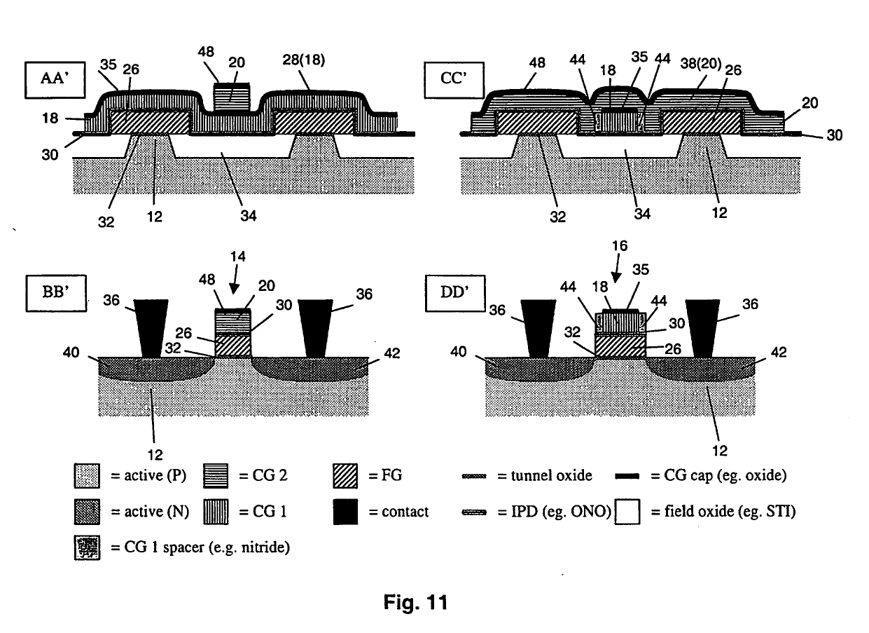

FIG. 11 shows four cross-sections of a second embodiment of a unit cell, after self-aligned source and drain implantations and contacts are made. FIG. 11 is the same as FIG. 3 except for the capping layer on top of the second polysilicon CG.

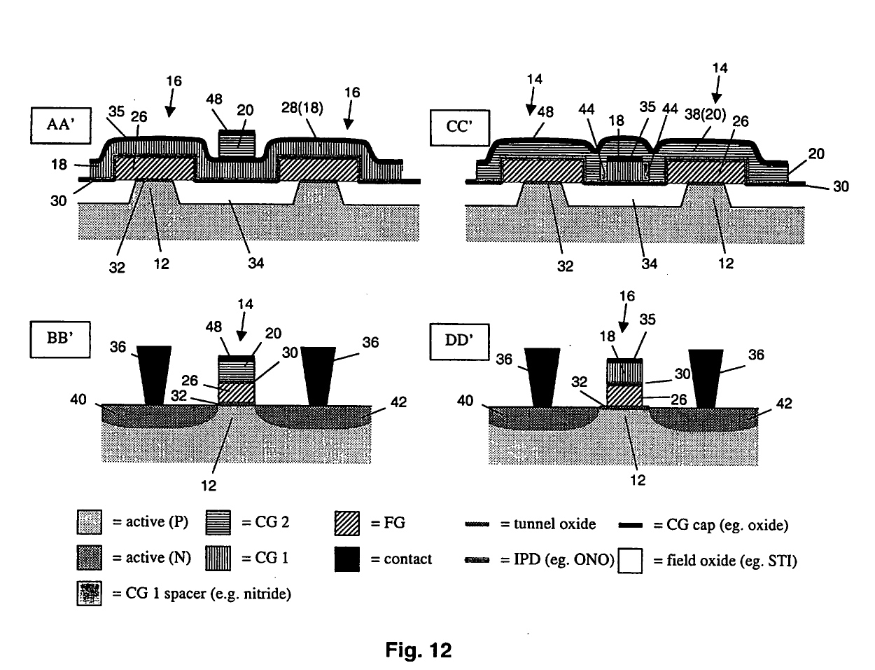

FIG. 12 shows four cross-sections of a third embodiment of a unit cell, wherein the transistor length is the same for all transistors.

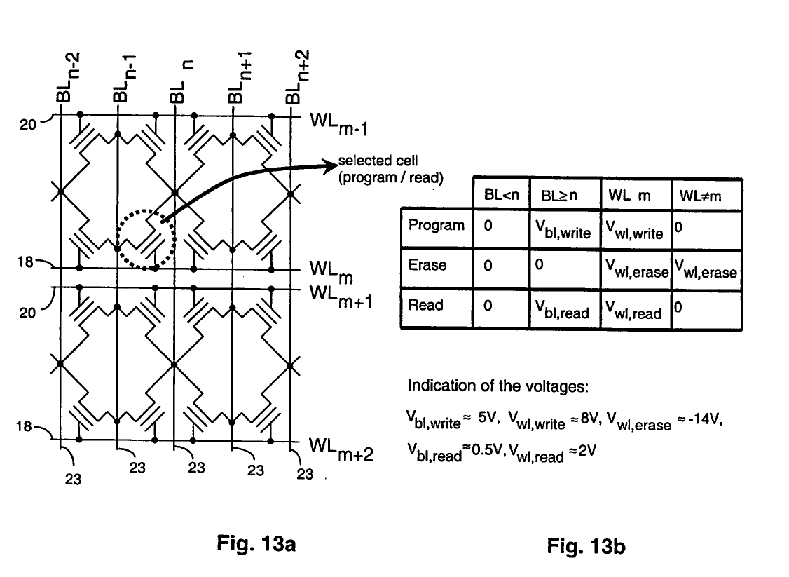

FIG. 13a is a symbol circuit diagram illustrating the equivalent electrical circuit of a part of the memory array as shown in FIG. 1. FIG. 13b shows the read, write and erase conditions for a memory array according to the circuit diagram of FIG. 13a.

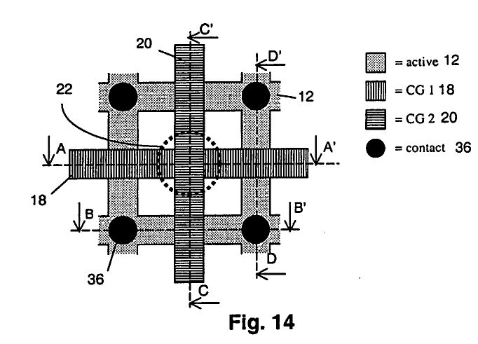

FIG. 14 is an enlarged view showing more detail of a second embodiment of one unit cell of the array of FIG. 1, but with the bitlines being taken away, the memory elements being charge trapping devices.

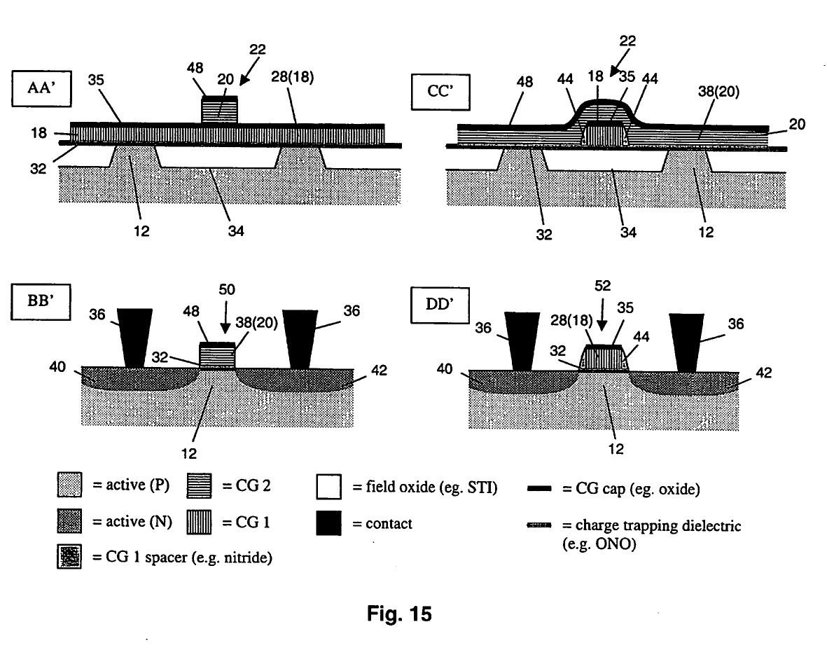

FIG. 15 shows four cross-sections of an embodiment of the unit cell of FIG. 14, according to the lines AA′, BB′, CC′ and DD′ in FIG. 14.

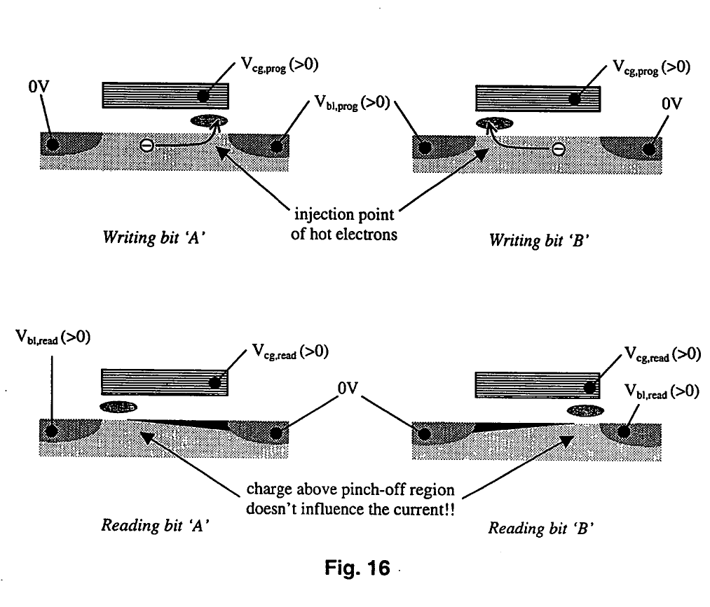

FIG. 16 illustrates writing and reading of a charge trapping device as used in FIG. 14 and FIG. 15.

In the different figures, the same reference numbers refer to the same or analogous elements.

The present invention will be described with respect to particular embodiments and with reference to certain drawings but the invention is not limited thereto but only by the claims. The drawings described are only schematic and are non-limiting. In the following reference will be made to processing silicon semiconductors as these are commonly used, but the present invention is not limited thereto and includes within its scope other semiconductor systems such as those based on germanium, silicon/germanium, gallium arsenide, etc. The skilled person will appreciate that although reference is made to materials conventionally used in silicon processing, equivalent materials are known to the skilled person in other semiconductor systems.

Throughout this description, the terms “horizontal”, “vertical”, “diagonal” are used to provide a co-ordinate system and for ease of explanation only. They do not need to, but may, refer to an actual physical direction of the device. Furthermore, the terms “column” and “row” are used to describe sets of array elements which are linked together. The linking can be in the form of a Cartesian array of rows and columns however the present invention is not limited thereto. As will be understood by those skilled in the art, columns and rows can be easily interchanged and it is intended in this disclosure that these terms be interchangeable. Also, non-Cartesian arrays may be constructed and are included within the scope of the invention. Accordingly the terms “row” and “column” should be interpreted widely. To facilitate in this wide interpretation, the claims refer to logically organized rows and columns. By this is meant that sets of memory elements are linked together in a topologically linear intersecting manner however, that the physical or topographical arrangement need not be so. For example, the rows may be circles and the columns radii of these circles and the circles and radii are described in this invention as “logically organized” rows and columns. Also, specific names of the various lines, e.g. bitline or wordline are intended to be generic names used to facilitate the explanation and to refer to a particular function and this specific choice of words is not intended to in any way limit the invention. It should be understood that all these terms are used only to facilitate a better understanding of the specific structure being described, and are in no way intended to limit the invention.

A schematic structure of a first embodiment of an array 10 of semiconductor memory devices according to the present invention is shown in FIG. 1. It comprises a substrate with active regions 12, and transistors 14, 16 organized in rows and columns in an array 10. Row-direction transistors 14 and column-direction transistors 16 are provided in the active regions 12. With “row-direction transistor” 14 is meant a transistor of which the direction from source to drain is located in the direction of a row of the array. With “column-direction transistor” is meant a transistor of which the direction from source to drain is located in the direction of a column of the array. In the example of FIG. 1, the row-direction and column-direction transistors 14, 16 are for example stacked gate floating gate transistors. The gates of some and preferably all transistors 16 in each row of column-direction transistors 16 are connected by a first wordline 18 and the gates of some and preferably all transistors 14 in each column of row-direction transistors 14 are connected by a second wordline 20. The first and second wordlines 18, 20 cross each other at cross-points 22. They are independent of, and insulated from each other. For clarity purposes, the floating gates underneath the wordlines 18, 20 have not been represented in FIG. 1.

A unit cell 24 of the array 10 (including the FGs) is shown schematically in FIG. 2. For clarity purposes, the (diagonal) bitlines 23 have not been drawn in FIG. 2. The cross-sections indicated by the dashed lines in FIG. 2 are sketched in FIG. 3.

The AA′ cross-section shows a vertical cross-section of two column-direction transistors 16 along a first wordline 18, each column-direction transistor 16 comprising a floating gate 26 and a control gate 28, insulated from each other by a dielectric 30, generally referred to as intergate dielectric or interpoly dielectric (IPD). The floating gate 26 and control gate 28 may be made from any suitable material, like semiconductor material or a metal, e.g. in silicon in which case the gates may be formed from polysilicon, and the dielectric 30 may be an interpoly dielectric (IPD) such as an oxide-nitride-oxide (ONO) layer for example. A tunnel oxide (TOx) 32 is present between the floating gate 26 of the column-direction transistors 16 and the active channel area 12. The channel 12 of subsequent column-direction transistors 16 are insulated from each other in the direction of the first wordline 18 by means of an insulating field 34, generally referred to as field oxide (FOx). These field areas can be implemented in different ways, e.g. local oxidation of silicon (LOCOS) or shallow trench insulation (STI). The control gates 28 of the column-direction transistors 16 on one row are connected to each other by means of the first wordline 18. On top of the first wordline 18, a cap layer 35 is provided, such as an oxide for example. The AA′ cross-section also shows, in between the vertical cross-sections of two column-direction transistors, a vertical cross-section of a cross-point 22 where the first wordline 18 and a second wordline 20 cross each other. Due to the cap layer 35 on top of the first wordline 18, both wordlines 18, 20 are insulated from each other.

The BB′ cross-section shows a vertical cross-section of a row-direction transistor 14 and two contacts 36. The row-direction transistor 14 comprises a floating gate 26, a control gate 38 and an intergate dielectric 30 between the floating gate 26 and the control gate 38. The floating gate 26 and control gate 38 may be made from polysilicon, and the so-called intergate dielectric 30 may for example be an ONO stack. A tunnel oxide 32 is present between the floating gate 26 of the row-direction transistor 14 and the active channel area 12. Underneath the contacts 36, a source region 40 and, a drain region 42 are present in the active channel area 12.

The CC′ cross-section shows a vertical cross-section of two row-direction transistors 14 along a second wordline 20. Each row-direction transistor comprises a floating gate 26 and a control gate 38, insulated from each other by an intergate dielectric 30. The floating gate 26 and control gate 38 may be made from polysilicon, and the intergate dielectric 30 may be an ONO stack for example. A tunnel oxide 32 is present between the floating gate 26 of the row-direction transistors 14 and the active channel area 12. The channel areas 12 of subsequent row-direction transistors 14 are insulated from each other in the direction of the second wordline 20 by means of an insulating field 34, such as local oxidation of silicon (LOCOS) or a shallow trench insulation (STI). The control gates 38 of the row-direction transistors 14 on one column are connected to each other by means of the second wordline 20. The CC′ cross-section also shows, in between the vertical cross-sections of two row-direction transistors 14, a vertical cross-section of a cross-point 22 where the first wordline 18 and the second wordline 20 cross each other. Due to the cap layer 35 on top of the first wordline 18, and due to insulators 44 at the sides of the second wordline 20, both wordlines 18, 20 are insulated from each other.

The DD′ cross-section shows a vertical cross-section of a column-direction transistor 16 and two contacts 36. The column-direction transistor 16 comprises a floating gate 26, a control gate 28 and an intergate dielectric 30 between the floating gate 26 and the control gate 28. The floating gate 26 and control gate 28 may be made from polysilicon, and the intergate dielectric 30 may for example be an ONO stack. A tunnel oxide 32 is present between the floating gate 26 of the column-direction transistor 16 and the active channel area 12. Underneath the contacts 36, a source region 40 and a drain region 42 are present in the active channel area 12. A cap layer 35 is present on top of the control gate 28, and insulators 44 are present at the sides of the control gate 28 which are upstanding with respect to the substrate surface.

It is to be noted that the cross-sections of FIG. 3 are only indicative, and that the exact cross-sections depend of the actual process flow used.

A comparison has been made of a memory array according to the present invention with a prior art array with a zigzag pattern of wordlines for a 0.18 μm CMOS embedded flash process. A prior art device has a contact-to-contact pitch of 1.12 μm (A=1.12² μm²/2 bits=0.63 μm²/bit). A unit cell according to the present invention has a contact-to-contact pitch of 0.88 μm, which leads to a cell size of 0.39 μm²/bit. The above values are dependent on the design rules used. If normal 1-transistor flash cells in a virtual ground scheme are made (using the same 0.18 μm CMOS process), a cell size of 0.46 μm² can be obtained.

A first example of a fabrication process of an array 10 according to the present invention is described step by step hereunder, referring to FIG. 4 to FIG. 11. The cross-sections shown in those drawings correspond to the cross-sections at the locations indicated by the dashed lines in FIG. 2.

FIG. 4 shows the situation at the start of the process. There is started from a substrate. In embodiments of the present invention, the term “substrate” may include any underlying material or materials that may be used, or upon which a device, a circuit or an epitaxial layer may be formed. In other alternative embodiments, this “substrate” may include a semiconductor substrate such as e.g. a doped silicon, a gallium arsenide (GaAs), a gallium arsenide phosphide (GaAsP), a germanium (Ge), or a silicon germanium (SiGe) substrate. The “substrate” may include for example, an insulating layer such as a SiO₂ or an Si₃N₄ layer in addition to a semiconductor substrate portion. Thus, the term substrate also includes silicon-on-glass, silicon-on sapphire substrates. The term “substrate” is thus used to define generally the elements for layers that underlie a layer or portions of interest. Also, the “substrate” may be any other base on which a layer is formed, for example a glass or metal layer. The active region 12 may be a well in the substrate. In the following, processing will mainly be described with reference to silicon processing but the skilled person will appreciate that the present invention may be implemented based on other semiconductor material systems and that the skilled person can select suitable materials as equivalents of the dielectric and conductive materials described below.

In the substrate, insulating regions 34 are provided (by conventional methods), such as thermally grown LOCOS regions or STI regions, in order to isolate subsequent memory cells from each other. Between two STI or LOCOS isolation zones 34, the remaining substrate will form an active area 12.

STI zones are preferred over LOCOS regions as they can be formed in a smaller dimension than that of the LOCOS regions, which allows the reduction of the cell dimensions, so that cell density can be increased. Therefore, in the following description, only STI zones are further considered, but it should be understood that the present invention includes the process steps described below carried out with LOCOS regions.

On top of the substrate with the insulating regions 34, a tunnel dielectric layer 32, such as an oxide layer comprising silicon dioxide, is formed, for example by thermally growing it in an oxygen-steam ambient, at a temperature between about 600 to 1000° C., to a thickness between about 6 to 15 nm, or by depositing it. In case the tunnel dielectric layer 32 is grown, it is only present on top of semiconductor substrate material, not on top of the insulating regions 34, as shown in FIG. 4. In case the tunnel dielectric layer 32 is deposited (not represented in the drawings), it is present both on top of semiconductor substrate material and on top of the insulating regions 34.

On top of the tunnel dielectric layer 32 and the insulating regions 34, a FG polysilicon layer 26 is deposited, which will later on form the FG of the memory elements. The deposition of the FG polysilicon layer 26 is preferably done by a CVD procedure, to a thickness between about 50 to 300 nm. Doping of the FG polysilicon layer 26 is either accomplished in situ, during deposition, e.g. via the addition of arsine or phosphine to a silane ambient, or via an ion implantation procedure, using for example arsenic or phosphorous ions applied to an intrinsically polysilicon layer.

To separate the adjacent floating gates in row and column directions, areas are etched in the FG polysilicon layer 26 (stop on tunnel dielectric layer 32 if this is present there, otherwise stop on insulating region 34) at positions 46 indicated in FIG. 5. These areas may be square in shape but they may also be other shapes such as octagonal, or generally polygonal or circular, oval or elliptical shapes. At those same locations, the tunnel dielectric layer 32, if present, can be removed as well, by selectively etching the tunnel dielectric layer 32 with regard to the insulating regions 34. FIG. 6 shows the cross sections after this etching step and a subsequent formation of an intergate or interpoly (IPD) dielectric layer 30. This intergate dielectric layer 30 comprises a dielectric material such as silicon oxide, and may be deposited via any suitable method such as an LPCVD or a PECVD procedure, to a thickness between about 10 to 30 nm. The intergate dielectric layer 30 preferably also comprises other insulating materials, e.g. an Oxide Nitride Oxide (ONO) stack, and may be formed or grown by conventional techniques. An ONO stack preferably comprises successive layers of silicon dioxide, silicon nitride and silicon dioxide.

After the deposition of the intergate dielectric layer 30, polysilicon for the control gates 28 of the column-direction transistors 16 is deposited and patterned. This means that a first CG polysilicon layer is deposited all over the intergate dielectric layer 30. The deposition of the first CG polysilicon layer 28 may for example be done by LPCVD procedures, to a thickness between about 50 to 300 nm. Doping of the first CG polysilicon layer 28 is either accomplished in situ, during deposition, via the addition of a suitable dopant impurity such as arsine or phosphine to a silane ambient, or via an ion implantation procedure, using such a dopant, e.g. arsenic or phosphorous ions applied to an intrinsically polysilicon layer. After deposition, the first CG polysilicon layer 28 is etched to form the first wordlines 18. Preferably, before patterning the first CG polysilicon layer 28, an insulating capping layer 35, such as e.g. an oxide layer, is grown or deposited over the first CG polysilicon layer 28. Thereafter both the insulating capping layer 35 and the first CG polysilicon layer 28 are patterned so as to form the first wordlines 18. The polysilicon etch should stop on the top layer of the intergate dielectric layer 30. The CG polysilicon layer 28 forming the first wordlines 18 is now terminated with a cap layer 35 which will serve as an insulator between crossing control gates in a direction away from the substrate surface, and which will also be used as a hard etch mask later on in the process. There where the first wordlines 18 overlay a floating gate 26, they form a control gate 28 of a column-direction transistor 16. The cross sections of a unit cell 24 of the array 10 after these steps are sketched in FIG. 7.

A lateral insulator between the two control gate groups can be made out of insulators 44 along the first wordlines 18, by a thermal side wall oxidation of wordlines 18. This is shown in FIG. 8. This thermal oxidation does not affect the side walls of the FG 26, as they are protected by an intergate dielectric layer 30.

Alternatively, the insulators 44 can be made by depositing an insulating layer, e.g. a nitride layer, over the complete structure, and then anisotropically etching this insulating layer. If the insulators 44 are made out of a different material than the top layer of the intergate dielectric layer 30 and the capping layer 35 (e.g. nitride, as in the example), a spacer etch which does not attack these two layers 30, 35 can be used. Otherwise, an additional deposition of dielectric material to compensate for the lost dielectric can be necessary. When using this method, spacers (not represented in FIG. 8) will also be present against the side walls of the FG 26. This does not hamper cell operation, but it causes different coupling coefficients for the row and column transistors, as the capacitive coupling between the CG and the FG at the side walls of the FGs is different for these two classes of transistors. At this stage of the process, a second CG polysilicon layer 38 can be deposited and patterned. This means that a second CG polysilicon layer 38 is deposited all over the structure as shown in FIG. 8. The deposition of the second CG polysilicon layer 38 may be done by LPCVD procedures, to a thickness between about 50 to 400 nm. Doping of the second CG polysilicon layer 38 is either accomplished in situ, during deposition, via the addition of a suitable dopant impurity such as arsine or phosphine to a silane ambient, or via an ion implantation procedure, using such a dopant, e.g. arsenic or phosphorous ions applied to an intrinsically polysilicon or amorphous layer. After deposition, the second CG polysilicon layer 38 is patterned by means of etching to form the second wordlines 20. Although not strictly necessary, the second CG polysilicon layer 38 can have the same capping layer 48 as the first CG polysilicon layer 28. The polysilicon etch of the second CG polysilicon layer 38 should stop on the intergate dielectric layer 30, on the capping layer 35 of the first wordlines 18 and on the CG insulators 44. There where the second wordlines 20 overlay a floating gate 26, they form a control gate 38 of a row-direction transistor 14. The result is shown in FIG. 9.

After stripping the photo resist used for patterning the second CG polysilicon layer 38 and the associated capping layer 48, the intergate dielectric layer 30, and the FG polysilicon layer 26 can be etched, using the capping layers 35, 48 on both wordlines 18, 20 and the lateral insulators 44 (spacers or thermal oxides) alongside wordlines 18 as hard masks. The tunnel dielectric layer 32 can be etched at this stage as well, or it can be etched at a later stage. It is to be noted that if the second wordline 20 does not have a suitable capping layer 48, the photo resist should not be removed before the etch of the intergate dielectric layer 30 and of the FG polysilicon layer 26 (and possibly the tunnel dielectric layer 32). The result after the FG/IPD etch is shown in FIG. 10. It is to be noted that the coupling coefficient of the row-direction and column-direction transistors will be different as the insulators 44 along the control gates 28 of the column-direction transistors 16 change the dimension of the FG 26.

Finally, back-end processing is done by means of methods generally known to persons skilled in the art, such as growing spacers against both gate stacks 14, 16 to enable both (1) highly doped drains (HDDs) and (2) silicided CGs, forming self-aligned source/drain implantations 40, 42 (whereby the CG/FG stacks serve as a mask protecting the channel areas from the source/drain implantations), possibly removing the tunnel dielectric layer 32 (if not done before), and forming contacts 36. In case of silicidation, the capping layers 35, 48 of both wordlines 18, 20 should be removed. At the cross-points 22 between both wordlines 18, 20, the first CG layer 28/18 (the lower one) will not be silicidized. A result is shown in FIG. 11.

As can be seen in FIG. 11, the row-direction and column-direction transistors 14, 16 do not have the same length, as the insulators 44 alongside the control gate 28/18 of the column-direction transistor 16 constitute a hard mask during the etch of the FG layer when forming the FG 26. This can be prevented by removing the insulators 44 prior to the definition of the FG 26 (i.e. between stages described in FIG. 9 and FIG. 10). This leads to a preferred embodiment as shown in FIG. 12. Both row-direction transistors 14 and column-direction transistors 16 now have the same transistor length. As the removal of the insulators 44 can be done with an unmasked etch if the insulators 44 are made out of a different material than the top layer of the intergate dielectric layer 30 and the capping layer 35 (e.g. nitride, as in the example given), the added process complexity for this embodiment is small. The removal of the spacers at this stage does not hamper silicidation later on in the process, because the generally used HDD offset spacers will prevent bridging.

In FIG. 13a, an equivalent electrical scheme of a memory structure according to the present invention is shown. Without changing the electrical functionality of the device, the row-direction and column-direction wordlines 18, 20 have been drawn parallel instead of orthogonal. As a result, the actual position of a transistor in the schematic array of FIG. 13a does not correspond to its physical location. FIG. 13a shows an interconnection of the memory cells in a virtual ground scheme. In a virtual ground scheme, every memory cell is connected between two adjacent bit lines instead of between a bit line (drain of the memory cell) and a common ground line (source), as in a conventional NOR scheme for instance. Often a virtual ground scheme is used to make very small cells, by using dopant diffused bit lines instead of metal bit lines with contacts.

The cells can for instance be programmed by Channel Hot Electron Injection (CHEI) and erased by Fowler-Nordheim (FN) tunneling to the channel. The appropriate voltage conditions for this way of operation are also indicated in FIG. 13b, as are the read conditions.

The following conditions may for example apply (these are examples only, other combinations are also possible):

Program by CHEI:
selected wordline: V_{wl,write} between 6 V and 12 V
non-selected wordlines: 0 V
bitlines up to selected bitline: 0 V
selected bitline: V_{bl,write} between 3 V and 8 V
bitlines from selected bitline: between 3 V and 8 V
(i.e. same voltage as the selected bit line)

Erase by FN:
all wordlines: V_{wl,erase} between −8 V and −20 V
all bitlines: 0 V

Read:
selected wordline: V_{wl,read} between 0.5 V and 2 V
non-selected wordlines: 0 V
bitlines up to selected bitline: 0 V
selected bitline: V_{bl,read} between 0.25 V and 3 V
bitlines from selected bitline: between 0.25 V and 3 V
(i.e. same voltage as the selected bit line)
   If a memory cell is to be selected for programming by CHEI, a voltage of approximately 8 Volt is applied to the control gate of the transistor memory element. The drain has to be biased with about 5 Volt, while the source is kept at a low voltage (e.g. 0 Volts). These conditions produce high-energy electrons (“hot” electrons) at the drain side of the transistor memory element. These hot electrons are attracted towards the floating gate and will contribute to an increase of the threshold voltage of the transistor memory element.

In order to erase the memory cell, a voltage of approximately −14 Volt is applied to the control gates of the transistor memory elements. The sources and the drains are kept at a low voltage (e.g. 0 Volts). Electrons are extracted from the floating gates by Fowler-Nordheim tunneling through the tunnel dielectric to the substrate interface. After an erase step, the threshold voltage of the transistor memory elements will be decreased. In the way described, the memory cells are all erased at once. If necessary, the cells can also be erased wordline by wordline. In that case, a voltage of approximately −14 Volt is applied to the selected wordline, while the other wordlines are kept at 0 Volt.

To read the memory cell, a predetermined voltage that is greater than the highest allowed threshold voltage of the transistor memory element in an erased memory cell, but less than the lowest allowed threshold voltage of the transistor memory element in a programmed memory cell, is applied to the control gate of the transistor memory element. This voltage may be chosen to be about 2 Volt. The source of the memory cell is kept at a low voltage (e.g. 0 Volt), while a small voltage (about 0.5 Volt) is applied to the drain of the memory cell. The latter one is needed to allow the verification if the memory cell conducts a current. If the memory cell conducts, then it has been erased and is not programmed (the memory cell is therefore at a first logic state, e.g. a one “1”). Conversely, if the memory cell does not conduct, then it has been programmed (the memory cell is therefore at a second logic state, e.g. a zero “0”). Thus, each memory cell may be read in order to determine whether it has been programmed (and therefore identify the logic state of the memory cell).

According to a second embodiment of the present invention, charge trapping devices or pinning devices are used instead of floating gate devices. In this class of devices, the information is stored as charge in a charge trapping layer (e.g. ONO stack) instead of on a floating gate. In case an ONO stack is used, the nitride layer in the ONO stack serves as the charge trapping layer. Instead of a nitride layer sandwiched between two non-trapping insulators such as oxide layers, small Si dots (so-called nano-crystals) encapsulated by oxide can also be used.

Apart from the simpler process (no FG polysilicon, spacers can be used for insulators 44 without the disadvantage of generating different characteristics for column and row transistors, no IPD, less topography), another advantage of this approach is the possibility to store two bits in one cell, as the charge can be injected at the source or at the drain, depending on the polarity of the Source/Drain current during program. Program, erase and read conditions are comparable to those for FG devices, except for the fact that the current has to be forced (write) or sensed (read) in two directions if the “two bits in one cell” operation is used. In case the “two bits in one cell” operation is used, the equivalent cell size is halved, i.e. for the example of the 0.18 μm CMOS process given above, an equivalent cell size of about 0.2 μm can be obtained.

FIG. 14 and FIG. 15 respectively show the unit cell and some cross sections indicated by the dashed lines in FIG. 14. In FIG. 14 the diagonal bitlines have not been shown for clarity purposes.

The AA′ cross-section shows a vertical cross-section of a first wordline 18. The first wordline 18 is separated from the substrate by means of a dielectric layer or stack of layers 32 with charge trapping properties. At positions where wordlines 18 cross active regions (separated from them by the charge trapping dielectric layer or stack of dielectric layers 32), they form CGs 28. At a certain location (cross-point 22), a second wordline 20 crosses the first wordline 18. Both wordlines are insulated from each other by means of capping layer 35 and side wall insulator 44 (thermal oxide or spacer).

The BB′ cross-section shows a vertical cross-section of a row-direction charge trapping device 50 and two contacts 36. The charge trapping device 50 comprises a dielectric layer or stack of layers 32 with charge trapping properties and a control gate 38. Contacts 36 are provided. Underneath the contacts 36, a source region 40 and a drain region 42 are present in the active channel area 12. A cap layer 48 is present on top of the control gate 38.

The CC′ cross-section shows a vertical cross-section of the second wordline 20. At positions where wordlines 20 cross active regions (separated from them by the charge trapping dielectric layer or stack of layers 32), they form CGs 38. At the cross-point 22 the second wordline 20 overlays the first wordline 18. The first and second wordlines 18, 20 are isolated from each other by means of a capping layer 35 on top of the first wordline 18, and lateral insulators 44 alongside the first wordline 18.

The DD′ cross-section shows a vertical cross-section of a column-direction charge trapping device 52 and two contacts 36. The column-direction charge trapping device 52 comprises a control gate 28 and a dielectric layer or combination of dielectric layers 32 between the control gate 28 and the active channel area 12. Contacts 36 are provided. Underneath the contacts 36, a source region 40 and a drain region 42 are present in the active channel area 12. A cap layer 35 is present on top of the control gate 28, and insulators 44 are present at the sides of the control gate 28 which are upstanding with respect to the substrate surface.

It is to be noted that the cross-sections of FIG. 15 are only indicative, and that the exact cross-sections depend of the actual process flow used.

As schematically shown in FIG. 16, the injection location of the charge in the charge trapping layer depends on the direction of the source-drain current during CHEI programming, which enables storage of two bits in one cell (one at the source and one at the drain side), thus doubling the memory density. During read, both situations can be discriminated when the transistor is brought into saturation: charge above the pinch-off region will not influence the source-drain current, whereas charge above the inversion layer will decrease the source-drain current, as is sketched in the lower part of FIG. 16. Programming, read-out and erasure of such a cell in which two bits can be stored, is described in WO 99/07000.

Thanks to the use of a virtual ground scheme (which implies the absence of common source lines), and the use of transistors in two directions (row-direction and column-direction), the density of the array 10 can be considerably higher than that of a conventional array of 1-transistor NVM cells.

In the drawings, the size of the different layers has been exaggerated for illustrative purposes. Furthermore, the drawings are not drawn to scale, and the dimensions of different layers with regard to each other is not kept correct.

It is to be understood that the section of the array depicted in FIG. 1 can be indefinitely extended in all directions depending on the desired size of the array.

While the invention has been shown and described with reference to preferred embodiments, it will be understood by those skilled in the art that various changes or modifications in form and detail may be made without departing from the scope and spirit of this invention.

1. An array of semiconductor memory devices logically organized in rows and columns, wherein semiconductor memory devices on a row are connected by a first wordline and semiconductor memory devices on a column are connected by a second wordline, the first and second wordlines crossing each other, wherein the first wordline and second wordline have no bends and are orthogonal to each another.

2. The array of claim 1, wherein the crossing of the first and second wordlines is an insulated crossing.

3. The array of claim 1, wherein the semiconductor memory devices are connected in a virtual ground scheme.

4. The array of claim 1, wherein the semiconductor memory devices are transistors having identical transistor length.

5. The array of claim 1, wherein the semiconductor memory devices are stacked gate floating gate memories.

6. The array of claim 1, wherein the semiconductor memory devices are charge trapping devices.

7. The array of claim 6, wherein at least one semiconductor memory device is adapted to store two bits.

8. A non-volatile memory including an array of semiconductor memory devices according to claim 1.

9. A method for manufacturing in or on a semiconductor substrate having a surface, an array of semiconductor memory devices logically organized in rows and columns, comprising the steps of providing a first wordline and providing a second wordline, the first and second wordlines crossing each other, wherein the first wordline and second wordline have no bends and are orthogonal to each other.

10. The method according to claim 9, furthermore comprising a step of providing insulation between the first wordline and the second wordline.

11. The method according to claim 10, wherein the step of providing insulation comprises providing an insulator in a direction away from the substrate surface.

12. The method according to claim 10, wherein the step of providing insulation comprises providing a lateral insulator.

13. The method according to claim 9, furthermore comprising a step of manufacturing the semiconductor memory devices.

14. The method according to claim 13, wherein the step of manufacturing the semiconductor memory devices comprises providing transistors with identical transistor length.

15. The method according to claim 13, wherein the step of manufacturing the semiconductor memory devices comprises steps for manufacturing stacked gate floating gate transistors.

16. The method according to claim 13, wherein the step of manufacturing the semiconductor memory elements comprises steps for manufacturing charge trapping devices.
